(19) United States
(12) Patent Application Publication
(10) Pub. No.: US 2025/0174617 A1
(43) Pub. Date: May 29, 2025

(54) SEMICONDUCTOR PACKAGE

(71) Applicant: Samsung Electronics Co., Ltd., Suwon-si (KR)

(72) Inventor: Junbyeong LEE, Suwon-si (KR)

(73) Assignee: Samsung Electronics Co., Ltd., Suwon-si (KR)

(21) Appl. No.: 18/820,444

(22) Filed: Aug. 30, 2024

(30) Foreign Application Priority Data
Nov. 29, 2023 (KR) 10-2023-0169024

(51) Int. Cl. H01L 25/18; H01L 23/00; H01L 23/31

(52) U.S. Cl. CPC H01L 25/18; H01L 23/3128; H01L 24/06; H01L 24/48; H01L 2224/06179; H01L 2224/48145; H01L 2224/48228; H01L 2225/06506; H01L 2225/0651; H01L 2225/06562; H01L 2924/1431

(57) ABSTRACT

A semiconductor package includes a package substrate having substrate pads thereon, semiconductor chips and a molding member. The semiconductor chips are stacked in a vertical direction on the package substrate. Each of the semiconductor chips includes chip pads, first to fourth bonding wires. The first bonding wire contacts a first substrate pad among the substrate pads and a first chip pad of the first semiconductor chip, the second bonding wire contacts the first substrate pad and a second chip pad of the second semiconductor chip, the third bonding wire contacts a second substrate pad among the substrate pads and a third chip pad of the first semiconductor chip, and the fourth bonding wire contacts the third chip pad and a fourth chip pad of the second semiconductor chip. The molding member is formed on the package substrate, and covers the semiconductor chips and the first to fourth bonding wires.

### CROSS-REFERENCE TO RELATED APPLICATION

This application claims priority under 35 U.S.C. § 119 to Korean Patent Application No. 10-2023-0169024, filed on Nov. 29, 2023 in the Korean Intellectual Property Office (KIPO), the contents of which are herein incorporated by reference in their entirety.

### BACKGROUND

### 1. Field

Example embodiments relate to a semiconductor package. More particularly, example embodiments relate to a semiconductor package including a plurality of stacked chips.

### 2. Description of the Related Art

In a multi-chip package including a plurality of semiconductor chips on a package substrate, chip pads on each of the semiconductor chips and substrate pads on the package substrate may be electrically connected to each other by bonding wires. It is needed to develop a method of stacking the semiconductor chips efficiently on the package substrate.

### SUMMARY

Example embodiments provide a semiconductor package having enhanced electrical characteristics.

According to example embodiments, there is provided a semiconductor package. The semiconductor package may include a package substrate having substrate pads; semiconductor chips stacked in a vertical direction on the package substrate, the semiconductor chips including at least a first semiconductor chip and a second semiconductor chip; a first bonding wire connecting a first chip pad of the first semiconductor chip with a corresponding one of a first set of the substrate pads; a second bonding wire connecting another of the first set of substrate pads with a second chip pad of the second semiconductor chip; a third bonding wire connecting a second substrate pad, among the substrate pads, and a third chip pad of the first semiconductor chip; a fourth bonding wire contacting the third chip pad with a fourth chip pad of the second semiconductor chip; and a molding member on the package substrate, the molding member covering the semiconductor chips and the first to fourth bonding wires.

According to example embodiments, there is provided a semiconductor package. The semiconductor package may a package substrate having substrate pads; semiconductor chips stacked in a vertical direction on the package substrate, the semiconductor chips including at least a first semiconductor chip and a second semiconductor chip, and each of the semiconductor chips including first and second edges, each of the first and second edges extending in a first direction to a first length, and the first and second edges being opposite to each other in a second direction crossing the first direction, third and fourth edges, each of the third and fourth edges extending in the second direction to a second length less than the first length, and the third and fourth edges being opposite to each other in the first direction, a first chip pad adjacent to at least one of the first edge or the second edge, and a second chip pad adjacent to at least one of the third edge or the fourth edge; a first bonding wire connecting the first chip pad of the first semiconductor chip with a corresponding one of a first set of the substrate pads; a second bonding wire contacting another of the first set of substrate pads with the first chip pad of the second semiconductor chip; a third bonding wire connecting a corresponding one of a second set of the substrate pads with the second chip pad of the first semiconductor chip; a fourth bonding wire connecting the second chip pad of the first semiconductor chip with the second chip pad of the second semiconductor chip; and a molding member on the package substrate, the molding member covering the semiconductor chips and the first to fourth bonding wires.

According to example embodiments, there is provided a semiconductor package. The semiconductor package may include a package substrate having substrate pads; first, second, third and fourth semiconductor chips stacked in a vertical direction on the package substrate; a first bonding wire connecting a first chip pad of the first semiconductor chip with a corresponding one of a first set of the substrate pads; a second bonding wire connecting another of the first substrate pads with a second chip pad of the second semiconductor chip; a third bonding wire connecting a third chip pad of the first semiconductor chip with a corresponding one of a second set of the substrate pads; a fourth bonding wire connecting the third chip pad of the first semiconductor chip with a fourth chip pad of the second semiconductor chip; a fifth bonding wire connecting a fifth chip pad of the third semiconductor chip with a corresponding one of a third set of the substrate pads; a sixth bonding wire contacting another of the third substrate pads with a sixth chip pad of the fourth semiconductor chip; a seventh bonding wire connecting a fourth substrate pad, among the substrate pads. with a seventh chip pad of the third semiconductor chip; an eighth bonding wire connecting the seventh chip pad and an eighth chip pad of the fourth semiconductor chip; and a molding member on the package substrate, the molding member covering the first to fourth semiconductor chips and the first to eighth bonding wires.

The semiconductor package in accordance with example embodiments may have a reduced planar area and an enhanced structural stability.

### BRIEF DESCRIPTION OF THE DRAWINGS

FIG. 1 is a plan view illustrating a semiconductor package in accordance with example embodiments, FIG. 2 is a cross-sectional view taken along line A-A′ of FIG. 1, and FIG. 3 is a cross-sectional view taken along line B-B′ of FIG. 1.

FIGS. 4 to 17 are plan views and cross-sectional views illustrating a method of manufacturing a semiconductor package in accordance with example embodiments.

FIGS. 18 and 19 are cross-sectional views illustrating semiconductor packages in accordance with example embodiments.

### DETAILED DESCRIPTION OF EXAMPLE EMBODIMENTS

Hereinafter, example embodiments will be explained in detail with reference to the accompanying drawings, wherein like reference numerals refer to like elements throughout.

In the following drawings, the same reference numerals refer to the same components, and the size of each component in the drawings may be exaggerated for clarity and convenience of explanation. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, whenever a range of values is enumerated, the range includes all values within the range as if recorded explicitly clearly, and may further include the boundaries of the range. Accordingly, the range of “X” to “Y” includes all values between X and Y, including X and Y. Meanwhile, the embodiments described below are merely illustrative, and various modifications are possible from these embodiments.

Hereinafter, two directions among horizontal directions that are substantially parallel to an upper surface of a substrate may be referred to as first and second directions D1 and D2, respectively, and a vertical direction substantially perpendicular to the upper surface of the substrate may be referred to as a third direction D3. Each of the first to third directions D1, D2 and D3 may include not only a direction shown in the drawings but also a direction that is inverse to the shown direction. It will also be understood that when an element is referred to as being “on” or “above” another element, the element may be in direct contact with the other element or other intervening elements may be present. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. The singular forms include the plural forms unless the context clearly indicates otherwise. It should be understood that, when a part “comprises” or “includes” an element in the specification, unless otherwise defined, other elements are not excluded from the part and the part may further include other elements.

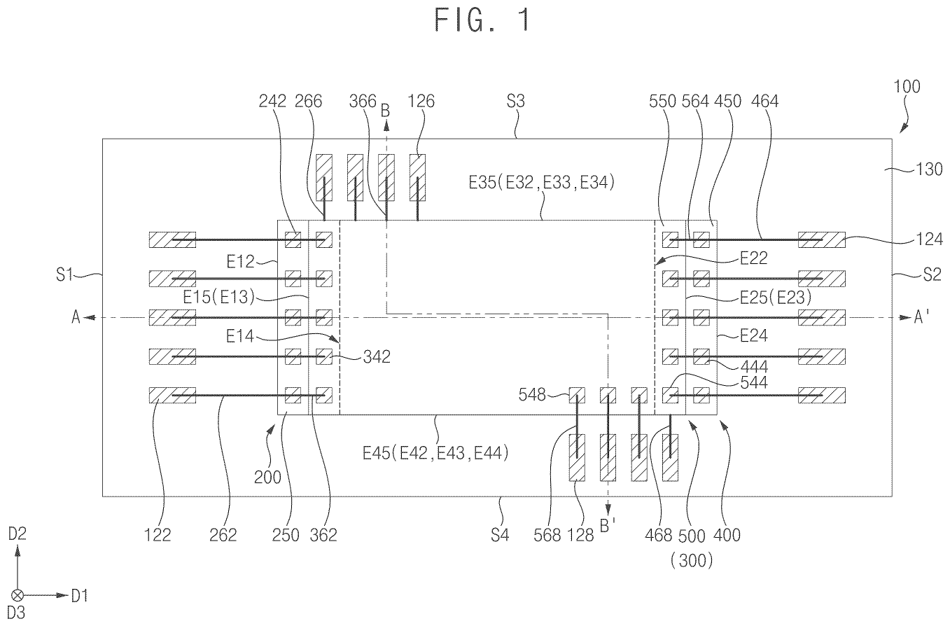

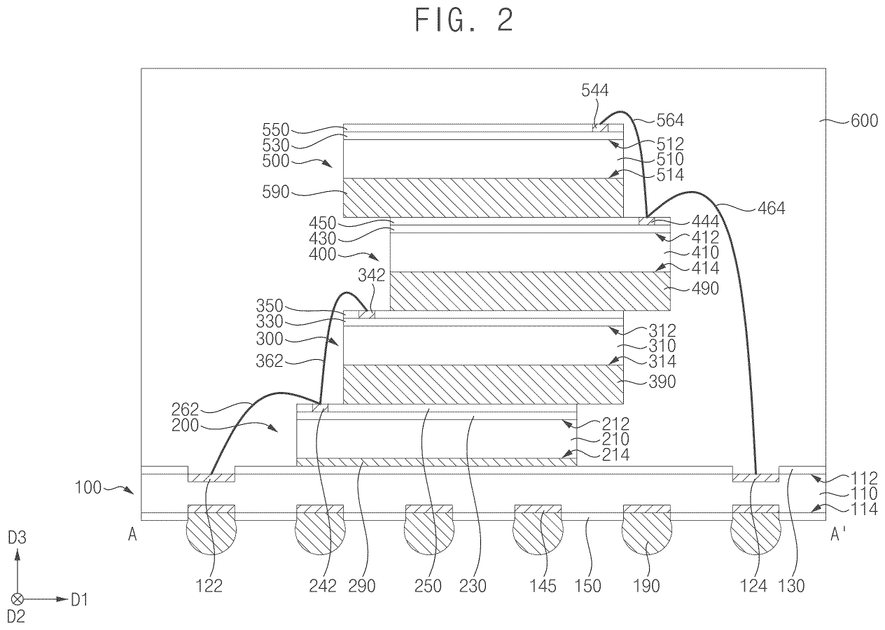

FIG. 1 is a plan view illustrating a semiconductor package in accordance with example embodiments, FIG. 2 is a cross-sectional view taken along line A-A′ of FIG. 1, and FIG. 3 is a cross-sectional view taken along line B-B′ of FIG. 1. FIG. 1 does not show a molding member 600 in order to avoid the complexity of the drawing.

Referring to FIGS. 1 to 3, the semiconductor package may include a package substrate structure 100, a plurality of semiconductor chips 200, 300, 400 and 500 sequentially stacked on the package substrate structure 100, and a molding member 600.

The semiconductor package may further include a plurality of bonding wires, e.g., first, second, third, fourth, fifth, sixth, seventh and eighth bonding wires 262, 266, 362, 366, 464, 468, 564 and 568, a plurality of bonding layers, e.g., first, second, third and fourth bonding layers 290, 390, 490 and 590, and an external connection member 190.

In example embodiments, the semiconductor package may be referred to as a multi-chip package (MCP), and the plurality of semiconductor chips may be the same as, substantially similar, and/or different from each other. Alternatively, the semiconductor package may be a system in package (SIP) including semiconductor chips, each of which may serve a specific functionality, in a package.

The first to fourth semiconductor chips 200, 300, 400 and 500 may have substantially the same (and/or substantially similar) structure and size, however, the inventive concepts may not be limited thereto. The semiconductor package may include four semiconductor packages sequentially stacked in the third direction D3, however, the inventive concepts may not be limited thereto. For example, the semiconductor package may include, e.g., 6, 8, or 10 semiconductor chips.

The package substrate structure 100 may include a package substrate 110 having first surface 112 and a second surface 114 opposite to each other in the third direction D3, a first substrate protective layer 130 on the first surface 112 of the package substrate 110, and a second substrate protective layer 150 beneath the second surface 114 of the package substrate 110. Each of the first and second substrate protective layers 130 and 150 may include an insulating material, e.g., an oxide (such as silicon oxide) and/or a nitride (such as silicon nitride).

Additionally, the package substrate 110 may include first and second side surfaces S1 and S2 opposite to each other in the first direction D1, and third and fourth sidewalls S3 and S4 opposite to each other in the second direction D2. In example embodiments, the first and second side surfaces S1 and S2 of the package substrate 110 may have a second length in the second direction D2, and the third and fourth side surfaces S3 and S4 of the package substrate 110 may have a first length in the first direction that may be greater than the second length.

In some example embodiments, the package substrate 110 may be a printed circuit board (PCB). The PCB may be a multi-layered circuit board including various circuit patterns, e.g., transistors, wirings, vias, contact plugs, conductive pads, etc.

In example embodiments, the circuit patterns may include a plurality of substrate pads 122, 124, 126, and 128 adjacent to the first surface 112 of the package substrate 110, and at least one fifth substrate pad 145 adjacent to the second surface 114 of the package substrate 110, which may not be covered by the first and second substrate protective layers 130 and 150. The first to fourth substrate pads 122, 124, 126, and 128 may be adjacent to the first to fourth side surfaces S1, S2, S3, and S4, respectively. In other words, a first set of substrate pads (e.g., first substrate pads 122) may be adjacent to the first side surface S1; a second set of substrate pads (e.g., second substrate pads 124) may be adjacent to the second side surface S2; a third set of substrate pads (e.g., third substrate pads 126) may be adjacent to the third side surface S3; and a fourth set of substrate pads (e.g., fourth substrate pads 128) may be adjacent to the fourth side surface S4,

Each of the first to fourth substrate pads 122, 124, 126, and 128 may be configured to transfer electrical signals from the package substrate 110 to the semiconductor chips 200, 300, 400 and 500, and may serve as a bonding pad, e.g., a bonding finger. The fifth substrate pad 145 may be configured to transfer electrical signals from the package substrate 110 to a module substrate that may be disposed under the package substrate 110, and may serve as an external connection pad. For example, an electrical path may be formed between each of the first to fourth substrate pads 122, 124, 126, and 128 and a corresponding fifth substrate pad 145.

The external connection member 190 may contact a lower surface of the fifth substrate pad 145, and an upper portion of the external connection member 190 may be covered by the second substrate protective layer 150.

Each of the first to fifth substrate pads 122, 124, 126, 128, and 145 may include a conductive material, such as a metal (e.g., copper, aluminum, nickel, etc.), and the external connection member 190 may include solder that is an eutectic alloy of, e.g., tin, silver, copper, lead, etc.

The first semiconductor chip 200 may include a first substrate 210 having first and second surfaces 212 and 214 opposite to each other in the third direction D3, and an insulating interlayer 230 stacked on the first surface 212 of the first substrate 210. In at least one embodiment, the insulating layer 230 may include at least a first insulating layer and a second insulating layer, sequentially stacked on the first surface 212. In at least one example embodiment, a thickness in the third direction D3 of the first semiconductor chip 200 may be in a range of about 40 micrometers (um) to about 60 um.

The first substrate 210 may include first and second edges E12 and E22 opposite to each other in the first direction D1, and third and fourth edges E32 and E42 opposite to each other in the second direction D2. In example embodiments, the first and second edges E12 and E22 of the first substrate 210 may have a fourth length in the second direction D2, and the third and fourth edges E32 and E42 of the first substrate 210 may have a third length in the first direction D1. The third length may be longer than the further length. In at least one example embodiment, the third length may be about 10 millimeters (mm), and the fourth length may be about 8 mm.

The first substrate 210 may include a semiconductor material (e.g., silicon, germanium, silicon-germanium, and/or a III-V group compound semiconductor (e.g., GaP, GaAs, GaSb, etc.). In example embodiments, the first substrate 210 may be a silicon-on-insulator (SOI) substrate or a germanium-on-insulator (GOI) substrate.

A circuit device, e.g., a logic device and/or a memory device may be formed on the first surface 212 of the first substrate 210. The memory device may include a volatile memory device such as a dynamic random access memory (DRAM) device, a static RAM (SRAM) device, etc., and/or a non-volatile memory device such as a flash memory device, an EEPROM device, etc. The circuit device may include circuit patterns, which may be covered by the first insulating interlayer 260.

The second insulating interlayer 230 may contain a wiring structure therein. The wiring structure may include, e.g., wirings, vias, contact plugs, etc.

The insulating interlayer 230 may include an oxide, e.g., silicon oxide, an insulating nitride, e.g., silicon nitride, or a low-k dielectric material. The wirings, the vias and the contact plugs may include, e.g., a metal, a metal nitride, a metal silicide, etc.

A first chip pad structure including first and second chip pads 242 and 246 may be formed on the second insulating interlayer 230, and may be electrically connected to the wiring structure in the second insulating interlayer 230. A sidewall of the first chip pad structure may be covered by a first chip protective layer 250 on the second insulating interlayer 230.

In example embodiments, a plurality of first chip pads 242 may be spaced apart from each other in the second direction D2 on a portion of the second insulating interlayer 230 adjacent to the first edge E12 of the first substrate 210, and a plurality of second chip pads 246 may be spaced apart from each other in the first direction D1 on a portion of the second insulating interlayer 230 adjacent to the third edge E32 of the first substrate 210. Thus, the first and second chip pads 242 and 246 included in the first chip pad structure may be disposed in an “L” shape, in a plan view, on a portion of the second insulating interlayer 230 adjacent to the first and third edges E12 and E32 of the first substrate 210.

In example embodiments, the number of the first chip pads 242 may be greater than the number of the second chip pads 246 in the first chip pad structure. FIG. 1 shows that the first chip pad structure includes five first chip pads 242 and the connection to three second chip pads 246, however, the inventive concepts may not be limited thereto.

In example embodiments, the first chip pad 242 may be configured as a signal pad for transferring signals, and the second chip pad 246 may be configured as a power pad or a ground pad for supplying power or grounding.

The first semiconductor chip 200 may be bonded with an upper surface of the first substrate protective layer 130 included in the package substrate structure 100 by the first bonding layer 290 that is attached beneath the second surface 214 of the first substrate 210. The first and second chip pads 242 and 246 included in the first semiconductor chip 200 may be adjacent to the first and third substrate pads 122 and 126, respectively, included in the package substrate structure 100.

The first bonding layer 290 may include, e.g., a die attach film (DAF). In at least one example embodiment, a thickness in the third direction D3 of the first bonding layer 290 may be about 10 um.

In example embodiments, the first bonding wire 262 may contact the first substrate pad 122 of the package substrate structure 100 and the first chip pad 242 of the first semiconductor chip 200, and thus may electrically connect the first substrate pad 122 and the first chip pad 242. Additionally, the second bonding wire 266 may contact the third substrate pad 126 of the package substrate structure 100 and the second chip pad 246 of the first semiconductor chip 200, and thus may electrically connect the third substrate pad 126 and the second chip pad 246.

The second semiconductor chip 300 may have a structure substantially the same as and/or similar to that of the first semiconductor chip 200. Thus, the second semiconductor chip 200 may include a second substrate 310 having first and second surfaces 312 and 314 opposite to each other in the third direction D3, and an insulating interlayer 330 may be stacked on the first surface 312 of the second substrate 310. In at least one embodiment, the insulating layer 330 may include at least a third insulating layer and a fourth insulating layer, sequentially stacked on the first surface 312.

The second substrate 310 may include first and second edges E13 and E23 opposite to each other in the first direction D1, and third and fourth edges E33 and E43 opposite to each other in the second direction D2. In example embodiments, the first and second edges E13 and E23 of the second substrate 310 may have the fourth length in the second direction D2, and the third and fourth edges E33 and E43 of the second substrate 310 may have the third length in the first direction D1.

A circuit device, e.g., a logic device or a memory device may be formed on the first surface 312 of the second substrate 310. The memory device may include circuit patterns, which may be covered by the third insulating interlayer. The fourth insulating interlayer 330 may contain a wiring structure therein.

A second chip pad structure including third and fourth chip pads 342 and 346 may be formed on the fourth insulating interlayer 330, and may be electrically connected to the wiring structure in the fourth insulating interlayer 330. A sidewall of the second chip pad structure may be covered by a second chip protective layer 350 on the fourth insulating interlayer 330.

In example embodiments, a plurality of third chip pads 342 may be spaced apart from each other in the second direction D2 on a portion of the fourth insulating interlayer 330 adjacent to the first edge E13 of the second substrate 310, and a plurality of fourth chip pads 346 may be spaced apart from each other in the first direction D1 on a portion of the fourth insulating interlayer 330 adjacent to the third edge E33 of the second substrate 310. Thus, the third and fourth chip pads 342 and 346 included in the second chip pad structure may be disposed in an “L” shape, in a plan view, on a portion of the fourth insulating interlayer 330 adjacent to the third and fourth edges E13 and E33 of the second substrate 310.

In example embodiments, the number of the third chip pads 342 may be greater than the number of the fourth chip pads 346 in the second chip pad structure. FIG. 1 shows that the second chip pad structure includes five third chip pads 342 and the connection to three fourth chip pads 346, however, the inventive concepts may not be limited thereto.

In example embodiments, the third chip pad 342 may be configured as a signal pad for transferring signals, and the fourth chip pad 346 may be configured as a power pad or a ground pad for supplying power or grounding.

The second semiconductor chip 300 may be bonded with an upper surface of the first chip protective layer 250 included in the first semiconductor chip 200 by the second bonding layer 390 that is attached beneath the second surface 314 of the second substrate 310. A lower surface of the second semiconductor chip 300 may not entirely, but partially contact an upper surface of the first semiconductor chip 200.

In example embodiments, the second semiconductor chip 300 may be stacked on the first semiconductor chip 300, and may be offset with respect to the first semiconductor chip 200 in the first direction D1 by, e.g., a distance of about 200 um to about 300 um. The third chip pads 342 of the second semiconductor chip 300 may be aligned in the first direction D1 with the first chip pads 242, respectively, of the first semiconductor chip 200, and some of the fourth chip pads 346 of the second semiconductor chip 300 may overlap the second chip pads 246, respectively, of the second semiconductor chip 300 in the third direction D3. Thus, the second edge E22 of the first semiconductor chip 200 may be covered by the second semiconductor chip 300, in a plan view.

The third and fourth edges E33 and E43 of the second semiconductor chip 300 may be partially aligned with the third and fourth edges E32 and E42, respectively, of the first semiconductor chip 200 in the third direction D3. Therefore, the second semiconductor chip 300 may not be offset, but may be aligned with the first semiconductor chip 200 in the second direction D2.

In example embodiments, the third bonding wire 362 may contact the first chip pad 242 of the first semiconductor chip 200 and the third chip pad 342 of the second semiconductor chip 300, and thus may electrically connect the first chip pad 242 and the third chip pad 342. Additionally, the fourth bonding wire 366 may contact the third substrate pad 126 of the package substrate structure 100 and the fourth chip pad 346 of the second semiconductor chip 300, and thus may electrically connect the third substrate pad 126 and the third chip pad 346.

The third semiconductor chip 400 may have a structure substantially the same as or similar to that of the first and second semiconductor chips 200 and 300. Thus, the third semiconductor chip 400 may include a third substrate 410 having first and second surfaces 412 and 414 opposite to each other in the third direction D3, and an insulating interlayer 430 may be stacked on the first surface 412 of the third substrate 410. In at least one embodiment, the insulating layer 430 may include at least a fifth insulating layer and a sixth insulating layer, sequentially stacked on the first surface 412.

The third substrate 410 may include first and second edges E14 and E24 opposite to each other in the first direction D1, and third and fourth edges E34 and E44 opposite to each other in the second direction D2. In example embodiments, the first and second edges E14 and E24 of the third substrate 410 may have the fourth length in the second direction D2, and the third and fourth edges E34 and E44 of the third substrate 410 may have the third length in the first direction D1.

A circuit device, e.g., a logic device or a memory device may be formed on the first surface 412 of the third substrate 410. The memory device may include circuit patterns, which may be covered by the fifth insulating interlayer. The sixth insulating interlayer 430 may contain a wiring structure therein.

A third chip pad structure including fifth and sixth chip pads 444 and 448 may be formed on the sixth insulating interlayer 430, and may be electrically connected to the wiring structure in the sixth insulating interlayer 430. A sidewall of the third chip pad structure may be covered by a third chip protective layer 450 on the sixth insulating interlayer 430.

In example embodiments, a plurality of fifth chip pads 444 may be spaced apart from each other in the second direction D2 on a portion of the sixth insulating interlayer 430 adjacent to the second edge E24 of the third substrate 410, and a plurality of sixth chip pads 448 may be spaced apart from each other in the first direction D1 on a portion of the sixth insulating interlayer 430 adjacent to the fourth edge E44 of the third substrate 410. Thus, the fifth and sixth chip pads 444 and 448 included in the third chip pad structure may be disposed in an “L” shape, in a plan view, on a portion of the sixth insulating interlayer 430 adjacent to the second and fourth edges E24 and E44 of the third substrate 410.

In example embodiments, the number of the fifth chip pads 444 may be greater than the number of the sixth chip pads 448 in the third chip pad structure. FIG. 1 shows that the third chip pad structure includes five fifth chip pads 444 and three sixth chip pads 448, however, the inventive concepts may not be limited thereto.

In example embodiments, the fifth chip pad 444 may be configured as a signal pad for transferring signals, and the sixth chip pad 448 may be configured as a power pad or a ground pad for supplying power or grounding.

The third semiconductor chip 400 may be bonded with an upper surface of the second chip protective layer 350 included in the second semiconductor chip 300 by the third bonding layer 490 that is attached beneath the second surface 414 of the third substrate 410. In example embodiments, a lower surface of the third semiconductor chip 400 may not entirely, but partially contact an upper surface of the second semiconductor chip 300.

In example embodiments, the first to third semiconductor chips 200, 300 and 400 may be stacked in a cascade shape. That is, the third semiconductor chip 400 may be stacked to be offset with respect to the second semiconductor chip 300 in the first direction D1 by, e.g., about 200 um to about 300 um, and the fifth and sixth chip pads 444 and 448 of the third semiconductor chip 400 may be disposed to be adjacent to the second and fourth substrate pads 124 and 128, respectively, of the package substrate structure 100. Thus, the second edge E23 of the second semiconductor chip 300 may be covered by the third semiconductor chip 400, in a plan view.

The third and fourth edges E34 and E44 of the third semiconductor chip 400 may be partially aligned with the third and fourth edges E33 and E43, respectively, of the second semiconductor chip 300 in the third direction D3. That is, the third semiconductor chip 400 may not be offset, but may be aligned with the first and second semiconductor chips 200 and 300 in the second direction D2.

In example embodiments, the fifth bonding wire 464 may contact the second substrate pad 124 of the package substrate structure 100 and the fifth chip pad 444 of the third semiconductor chip 400, and thus may electrically connect the second substrate pad 124 and the fifth chip pad 444. Additionally, the sixth bonding wire 468 may contact the fourth substrate pad 128 of the package substrate structure 100 and the sixth chip pad 448 of the third semiconductor chip 400, and thus may electrically connect the fourth substrate pad 128 and the sixth chip pad 448.

The fourth semiconductor chip 500 may have a structure substantially the same as or similar to that of the first to third semiconductor chips 200, 300 and 400. Thus, the fourth semiconductor chip 500 may include a fourth substrate 510 having first and second surfaces 512 and 514 opposite to each other in the third direction D3, and a seventh insulating interlayer and an eighth insulating interlayer 530 may be sequentially stacked on the first surface 512 of the fourth substrate 510.

The fourth substrate 510 may include first and second edges E15 and E25 opposite to each other in the first direction D1, and third and fourth edges E35 and E45 opposite to each other in the second direction D2. In example embodiments, the first and second edges E15 and E25 of the fourth substrate 510 may have the fourth length in the second direction D2, and the third and fourth edges E35 and E45 of the fourth substrate 410 may have the third length in the first direction D1.

A circuit device, e.g., a logic device or a memory device may be formed on the first surface 512 of the fourth substrate 510. The memory device may include circuit patterns, which may be covered by the seventh insulating interlayer. The eighth insulating interlayer 530 may contain a wiring structure therein.

A fourth chip pad structure including seventh and eighth chip pads 544 and 548 may be formed on the eighth insulating interlayer 530, and may be electrically connected to the wiring structure in the eighth insulating interlayer 530. A sidewall of the fourth chip pad structure may be covered by a fourth chip protective layer 550 on the eighth insulating interlayer 530.

In example embodiments, a plurality of seventh chip pads 544 may be spaced apart from each other in the second direction D2 on a portion of the eighth insulating interlayer 530 adjacent to the second edge E25 of the fourth substrate 510, and a plurality of eighth chip pads 548 may be spaced apart from each other in the first direction D1 on a portion of the eighth insulating interlayer 530 adjacent to the fourth edge E45 of the fourth substrate 410. Thus, the seventh and eighth chip pads 544 and 548 included in the fourth chip pad structure may be disposed in an “L” shape, in a plan view, on a portion of the eighth insulating interlayer 530 adjacent to the second and fourth edges E25 and E45 of the fourth substrate 510.

In example embodiments, the number of the seventh chip pads 544 may be greater than the number of the eighth chip pads 548 in the fourth chip pad structure. FIG. 1 shows that the fourth chip pad structure includes five seventh chip pads 544 and three eighth chip pads 548, however, the inventive concepts may not be limited thereto.

In example embodiments, the seventh chip pad 544 may be a signal pad for transferring signals, and the eighth chip pad 548 may be a power pad or a ground pad for supplying power or grounding.

The fourth semiconductor chip 500 may be bonded with an upper surface of the third chip protective layer 450 included in the third semiconductor chip 400 by the fourth bonding layer 590 that is attached beneath the second surface 514 of the fourth substrate 510. In example embodiments, a lower surface of the fourth semiconductor chip 500 may not entirely, but partially contact an upper surface of the third semiconductor chip 400.

In example embodiments, the fourth semiconductor chip 500 may be stacked on the third semiconductor chip 400, and may be offset with respect to the third semiconductor chip 400 in the first direction D1 by, e.g., a distance of about 200 um to about 300 um. The seventh chip pads 544 of the fourth semiconductor chip 500 may be aligned in the first direction D1 with the fifth chip pads 444, respectively, of the third semiconductor chip 400, and some of the eighth chip pads 548 of the fourth semiconductor chip 500 may overlap the sixth chip pads 448, respectively, of the third semiconductor chip 400 in the third direction D3. Thus, the first edge E14 of the third semiconductor chip 400 may be covered by the fourth semiconductor chip 500, in a plan view.

The third and fourth edges E35 and E45 of the fourth semiconductor chip 500 may be partially aligned with the third and fourth edges E34 and E44, respectively, of the third semiconductor chip 400 in the third direction D3. That is, the fourth semiconductor chip 500 may not be offset, but may be aligned with the first to third semiconductor chips 200, 300 and 400 in the second direction D2.

In example embodiments, the seventh bonding wire 564 may contact the seventh chip pad 544 of the fourth semiconductor chip 500 and the fifth chip pad 444 of the third semiconductor chip 400, and thus may electrically connect the seventh chip pad 544 and the fifth chip pad 444. Additionally, the eighth bonding wire 568 may contact the fourth substrate pad 128 of the package substrate structure 100 and the eighth chip pad 548 of the fourth semiconductor chip 500, and thus may electrically connect the fourth substrate pad 128 and the eighth chip pad 548.

Each of the second to fourth bonding layers 390, 490 and 590 may include an adhesive material, e.g., a DAF. In at least one example embodiment, a thickness in the third direction D3 of each of the second to fourth bonding layers 390, 490 and 590 may be in a range of about 40 um to about 60 um.

Each of the first to eighth bonding wires 262, 266, 362, 366, 464, 468, 564 and 568 may include a flexible conductive material such as a metal (e.g., copper, aluminum, tungsten, nickel, molybdenum, gold, silver, chromium, tin, titanium, etc.).

The molding member 600 may be formed on the package substrate structure 100, and may cover the first to fourth semiconductor chips 200, 300, 400 and 500, the first to fourth bonding layers 290, 390, 490 and 590, and the first to eighth bonding wires 262, 266, 366, 464, 468, 564 and 568.

In example embodiments, a portion of the second bonding wire 266 may be covered by the second bonding layer 390, a portion of the fourth bonding wire 366 may be covered by the third bonding layer 490, and a portion of the sixth bonding wire 466 may be covered by the fourth bonding layer 590.

In the semiconductor package, the first to fourth semiconductor chips 200, 300, 400 and 500 sequentially stacked in the third direction D3 may not be offset in the second direction D2. Thus, the second and fourth chip pads 246 and 346 of the first and second semiconductor chips 200 and 300, respectively, may be electrically connected to the third substrate pad 126 of the package substrate 110 through the second and fourth bonding wires 266 and 366, respectively, and the sixth and eighth chip pads 448 and 548 of the third and fourth semiconductor chips 400 and 500, respectively, may be electrically connected to the fourth substrate pad 128 of the package substrate 110 through the sixth and eighth bonding wires 468 and 568, respectively.

That is, two different bonding wires (e.g., the second and fourth bonding wires 266 and 366) may be connected to the third substrate pad 126, and two different bonding wires (e.g., the sixth and eighth bonding wires 468 and 568) may be connected to the fourth substrate pad 128, and thus a reflective wave may increase due to the knee phenomenon on each of the third and fourth substrate pads 126 and 128, which may deteriorate the operation characteristics of the semiconductor package.

However, since each of the second, fourth, sixth and eighth chip pads 246, 346, 448 and 548 is not configured as a signal pad, but a power pad or a ground pad, the deterioration of the operation characteristics does not cause a serious problem. Additionally, the first to fourth semiconductor chips 200, 300, 400 and 500 may be stacked not to be offset, but to be aligned with each other in the second direction D2. Thus, a planar area of a semiconductor chip structure including the first to fourth semiconductor chips 200, 300, 400 and 500 may not increase, and a structural instability of the semiconductor chip structure due to the overhang structure may be reduced.

In the semiconductor package, the first to third semiconductor chips 200, 300 and 400 may be stacked in a cascade shape in the first direction D1, and the fourth semiconductor chip 500 may be stacked on and offset with respect to the third semiconductor chip 400 in the first direction D1.

Thus, the first and third chip pads 242 and 342 of the first and second semiconductor chips 200 and 300, respectively, may be electrically connected to the first substrate pad 122 by a chip-to-chip wire bonding method through the first and third bonding wires 262 and 362, and the fifth and seventh chip pads 444 and 544 of the third and fourth semiconductor chips 400 and 500, respectively, may be electrically connected to the second substrate pad 124 by a chip-to-chip wire bonding method through the fifth and seventh bonding wires 464 and 564.

That is, only one bonding wire (e.g., the first and fifth bonding wires 262 and 464) may be connected to the first and second substrate pads 122 and 124, respectively, and thus the deterioration of the operation characteristics due to the knee phenomenon and/or knee voltage may be mitigated and/or prevented at the first and second substrate pads 122 and 124. Particularly, each of the first, third, fifth and seventh chip pads 242, 342, 444 and 548 is a signal pad, and thus the mitigation and/or prevention of the deterioration of the operation characteristics is meaningful.

Additionally, a total length of the bonding wires from the first substrate pad 122 via the first chip pad 242 to the third chip pad 342, that is, a sum of lengths of the first and third bonding wires 262 and 362 may be smaller than a total length of two different bonding wires contacting the first substrate pad 122 to the respective first and third chip pads 242 and 342 by, e.g., about 60 um to about 100 um. Likewise, a total length of the bonding wires from the second substrate pad 124 via the fifth chip pad 444 to the seventh chip pad 544, that is, a sum of lengths of the fifth and seventh bonding wires 464 and 564 may be smaller than a total length of two different bonding wires contacting the second substrate pad 124 to the respective fifth and seventh chip pads 444 and 544 by, e.g., about 60 um to about 100 um.

Thus, a speed of transferring electrical signal between the package substrate 110 and each of the first to fourth semiconductor chips 200, 300, 400 and 500 may be enhanced, and the semiconductor package may have a high speed operation characteristic.

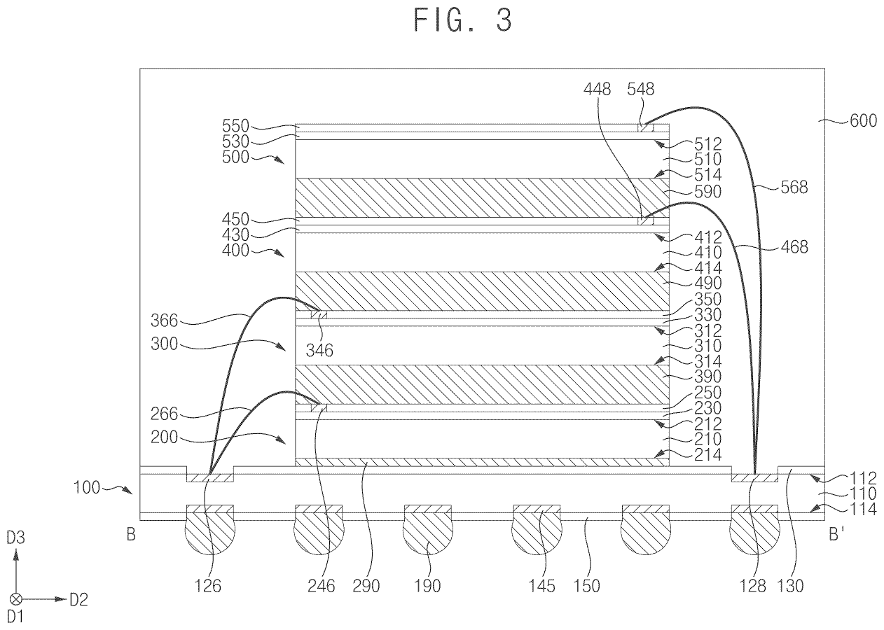

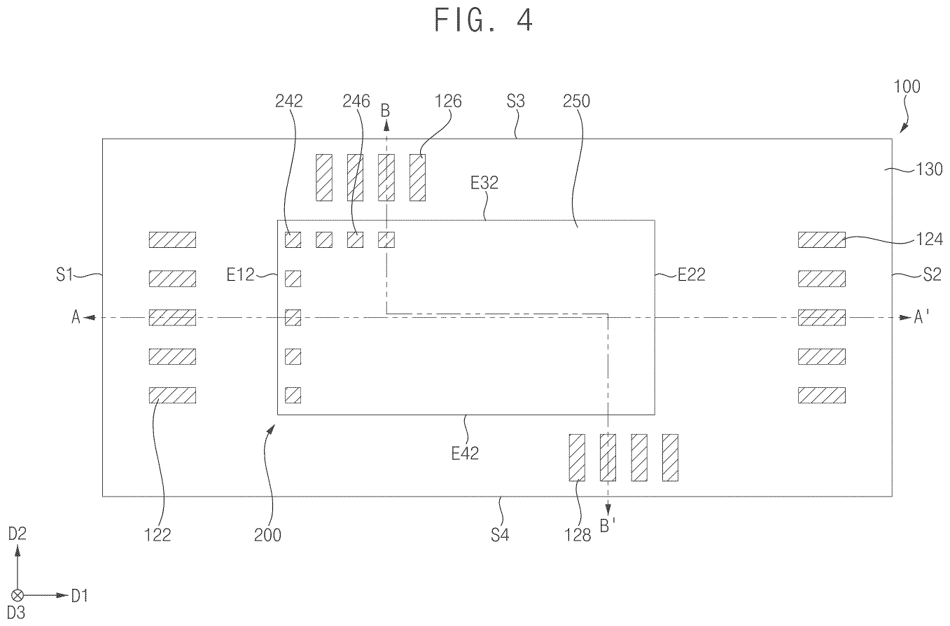

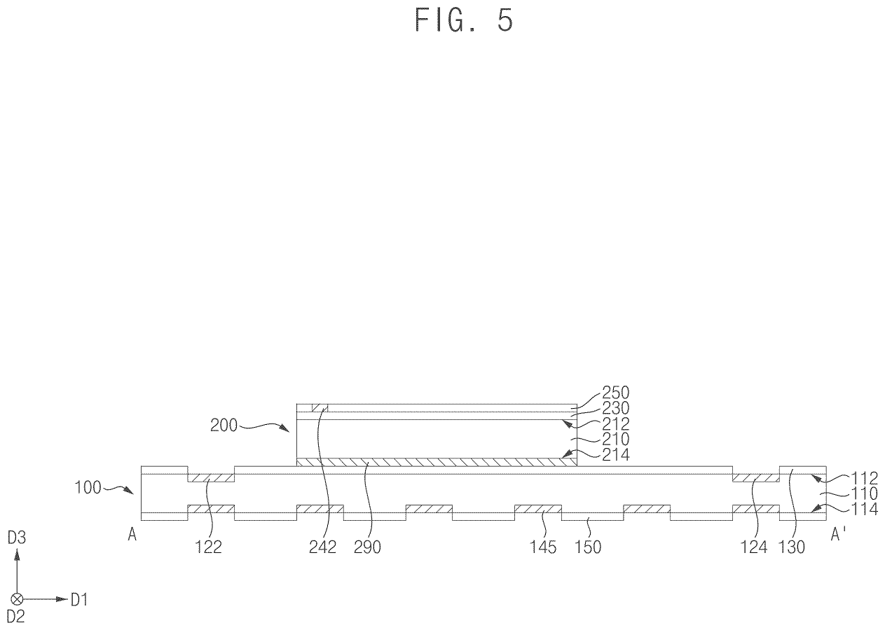

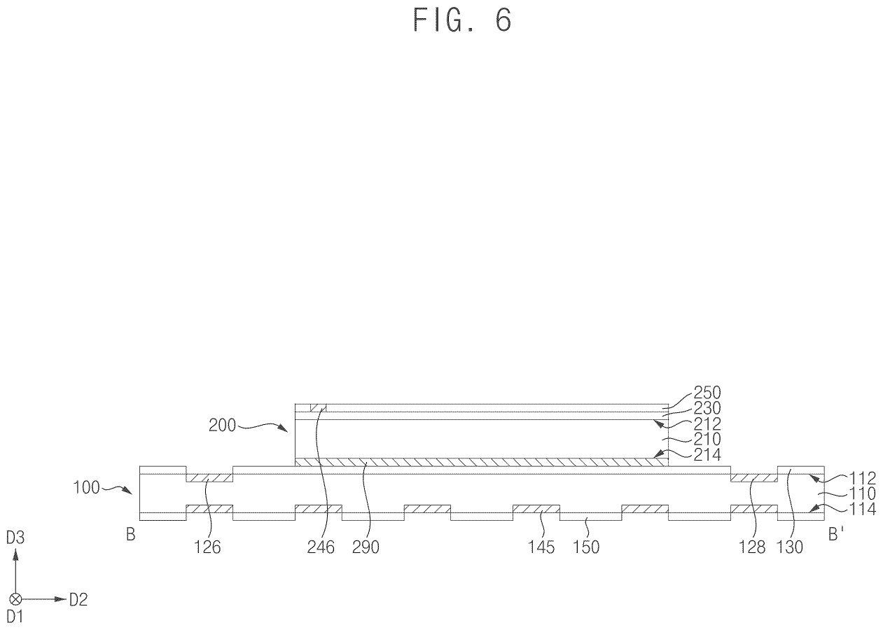

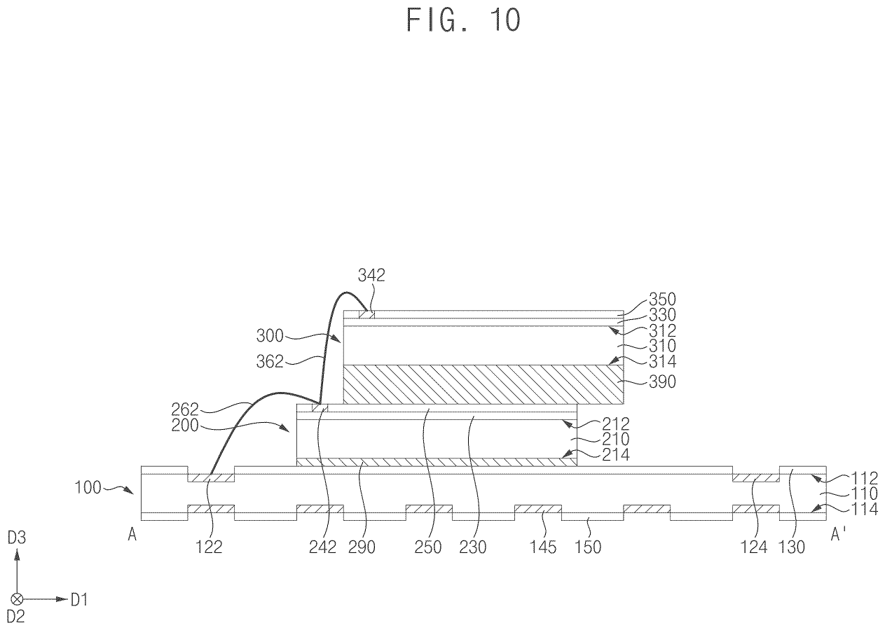

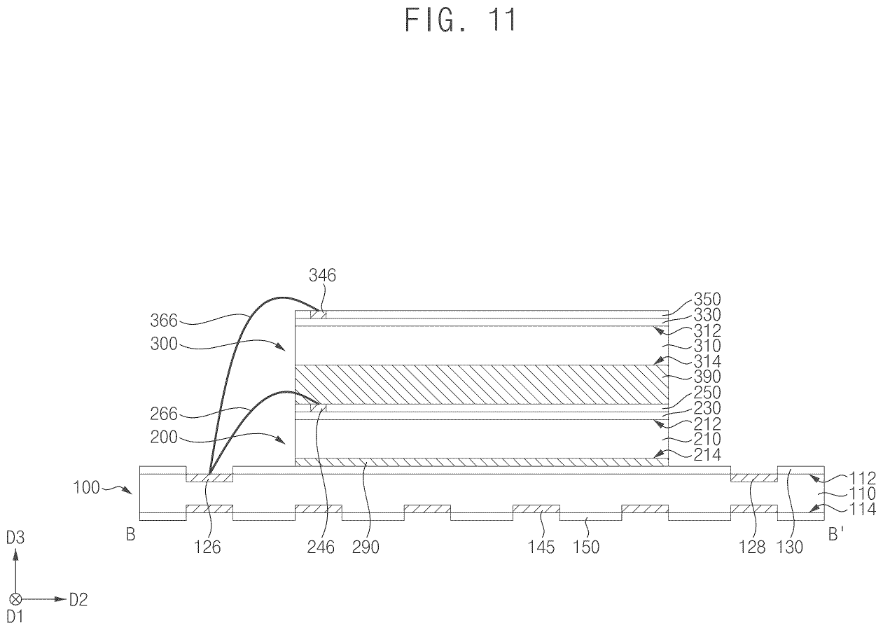

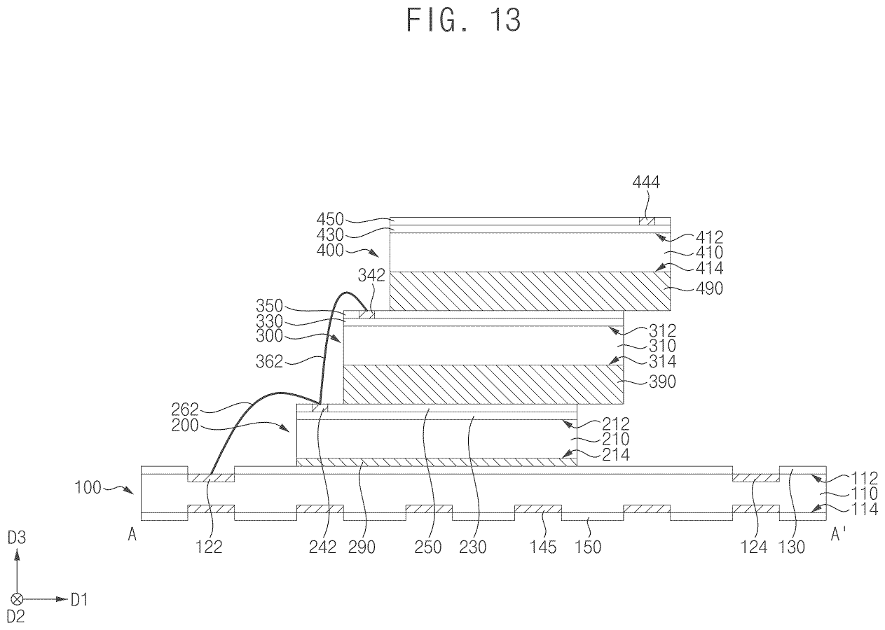

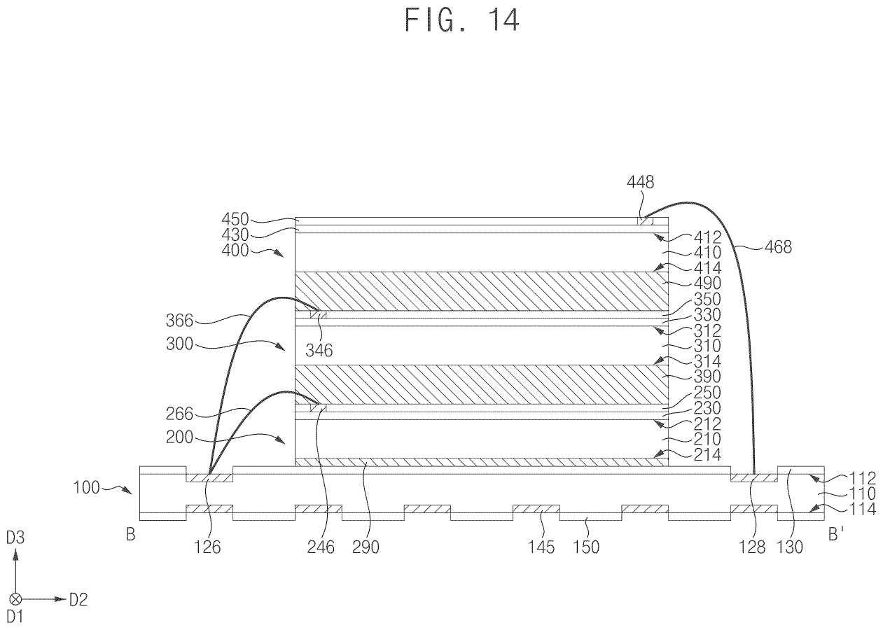

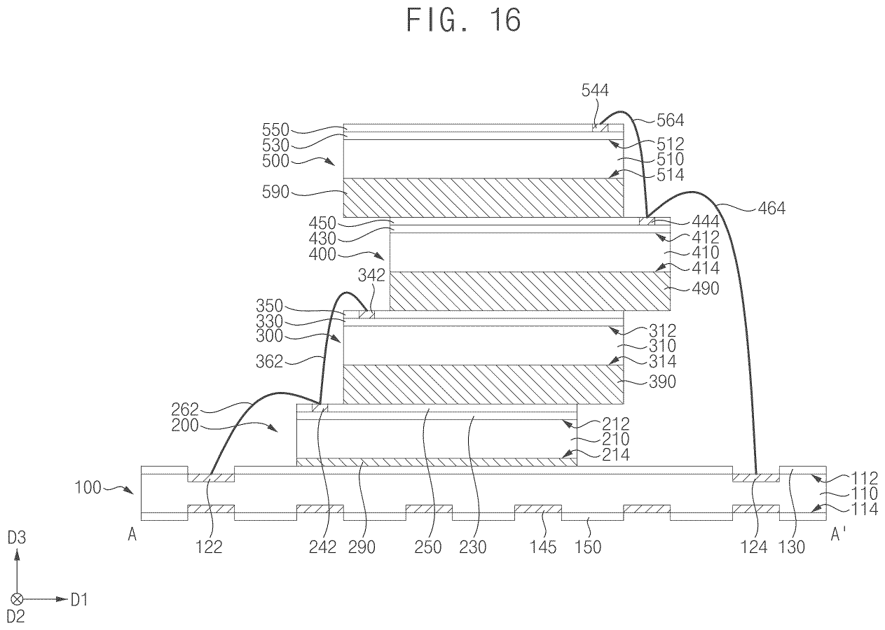

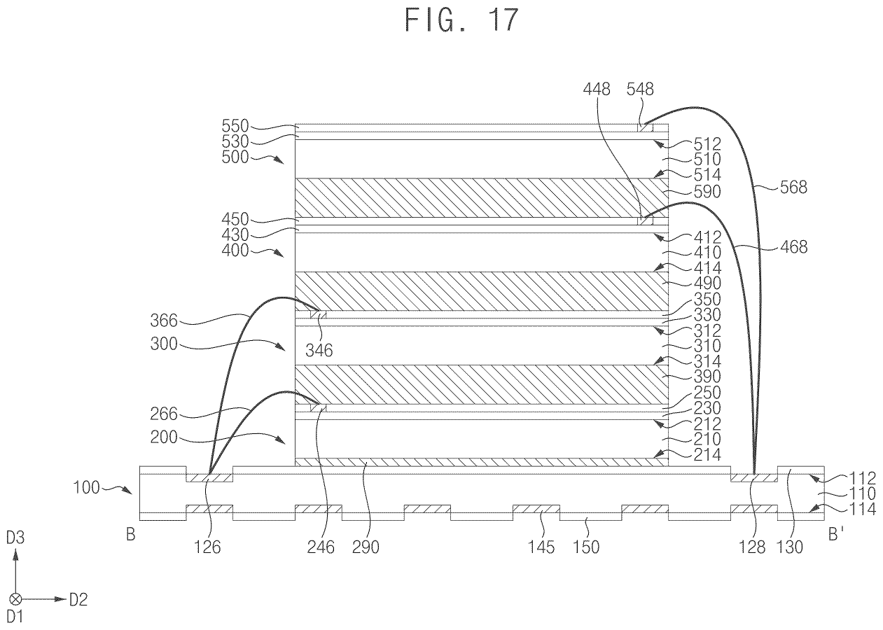

FIGS. 4 to 17 are plan views and cross-sectional views illustrating a method of manufacturing a semiconductor package in accordance with example embodiments. More specifically, FIGS. 4, 7, 9, 12 and 15 are the plan views, and FIGS. 5, 10, 13 and 16 are cross-sectional views taken along lines A-A′ of corresponding plan views, respectively, and FIGS. 6, 8, 11, 14 and 17 are cross-sectional views taken along lines B-B′ of corresponding plan views, respectively.

Referring to FIGS. 4 to 6, a first semiconductor chip 200 may be mounted on a package substrate structure 100.

In example embodiments, the package substrate structure 100 may include a package substrate 110 having first and second surfaces 112 and 114 opposite to each other in the third direction D3, a first substrate protective layer 130 on the first surface 112 of the package substrate 110, and a second substrate protective layer 150 beneath the second surface 114 of the package substrate 110.

Additionally, the package substrate 110 may include first and second side surfaces S1 and S2 opposite to each other in the first direction D1, and third and fourth side surfaces S3 and S4 opposite to each other in the second direction D2.

The package substrate 110 may be, e.g., PCB, which is a multi-layered circuit board including various circuit patterns, e.g., transistors, wirings, vias, contact plugs, conductive pads, etc. In example embodiments, the circuit patterns may include first, second, third and fourth substrate pads 122, 124, 126 and 128 adjacent to the first surface 112 of the package substrate 110, and a fifth substrate pad 145 adjacent to the second surface 114 of the package substrate 110. The first to fourth substrate pads 122, 124, 126 and 128 may be adjacent to the first to fourth side surfaces S1, S2, S3 and S4, respectively.

The first semiconductor chip 200 may include a first substrate 210 having first and second surfaces 212 and 214 opposite to each other in the third direction D3, and an insulating interlayer 230 may be stacked on the first surface 212 of the first substrate 210. In at least one embodiment, the insulating layer 230 may include at least a first insulating layer and a second insulating layer, sequentially stacked on the first surface 212.

The first substrate 210 may include first and second edges E12 and E22 opposite to each other in the first direction D1, and third and fourth edges E32 and E42 opposite to each other in the second direction D2.

A circuit device including circuit patterns may be formed on the first surface 212 of the first substrate 210, which may be covered by the first insulating interlayer. The second insulating interlayer 230 may contain a wiring structure therein.

A first chip pad structure including first and second chip pads 242 and 246 may be formed on the second insulating interlayer 230, and may be electrically connected to the wiring structure in the second insulating interlayer 230. A sidewall of the first chip pad structure may be covered by a first chip protective layer 250 on the second insulating interlayer 230.

In example embodiments, a plurality of first chip pads 242 may be spaced apart from each other in the second direction D2 on a portion of the second insulating interlayer 230 adjacent to the first edge E12 of the first substrate 210, and a plurality of second chip pads 246 may be spaced apart from each other in the first direction D1 on a portion of the second insulating interlayer 230 adjacent to the third edge E32 of the first substrate 210.

The first semiconductor chip 200 may be bonded with an upper surface of the first substrate protective layer 130 included in the package substrate structure 100 by a first bonding layer 290 that is attached beneath the second surface 214 of the first substrate 210. The first and second chip pads 242 and 246 included in the first semiconductor chip 200 may be adjacent to the first and third substrate pads 122 and 126, respectively, included in the package substrate structure 100.

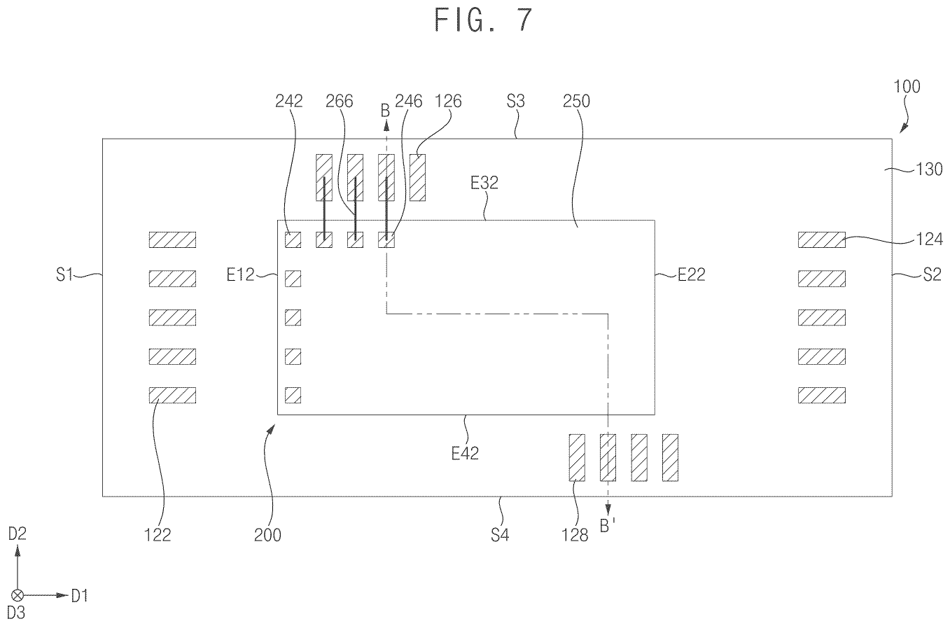

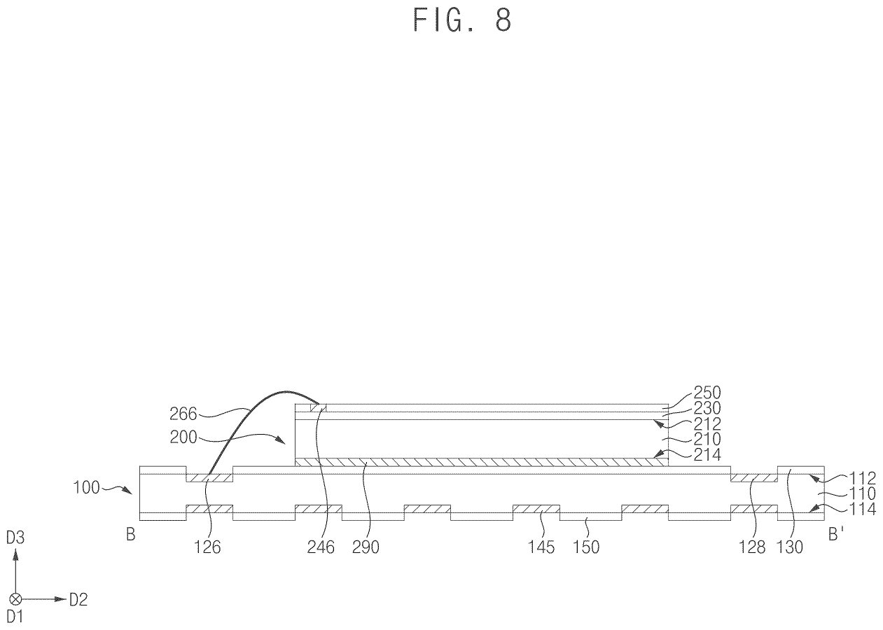

Referring to FIGS. 7 and 8, a wire bonding process may be performed such that a second bonding wire 266 may contact the third substrate pad 126 of the package substrate structure 100 and the second chip pad 246 of the first semiconductor chip 200. Thus, the third substrate pad 126 and the second chip pad 246 may be electrically connected to each other.

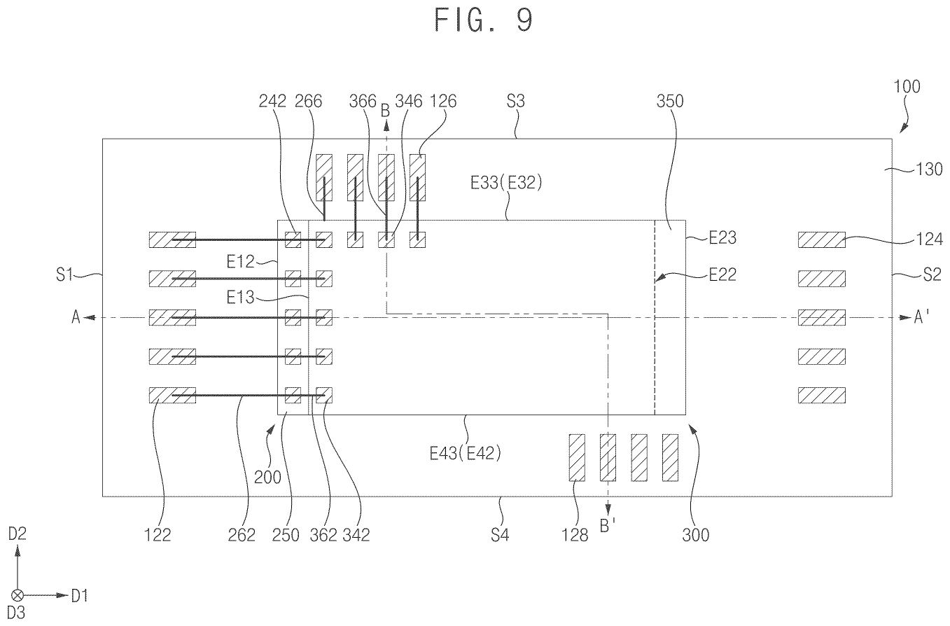

Referring to FIGS. 9 to 11, a second semiconductor chip 300 may be stacked on the first semiconductor chip 200.

In example embodiments, the second semiconductor chip 300 may have a structure substantially the same as or similar to that of the first semiconductor chip 200. Thus, the second semiconductor chip 200 may include a second substrate 310 having first and second surfaces 312 and 314 opposite to each other in the third direction D3, and a third insulating interlayer and a fourth insulating interlayer 330 may be sequentially stacked on the first surface 312 of the second substrate 310.

The second substrate 310 may include first and second edges E13 and E23 opposite to each other in the first direction D1, and third and fourth edges E33 and E43 opposite to each other in the second direction D2. A circuit device including circuit patterns may be formed on the first surface 312 of the second substrate 310, which may be covered by the third insulating interlayer. The fourth insulating interlayer 330 may contain a wiring structure therein.

A second chip pad structure including third and fourth chip pads 342 and 346 may be formed on the fourth insulating interlayer 330, and may be electrically connected to the wiring structure in the fourth insulating interlayer 330. A sidewall of the second chip pad structure may be covered by a second chip protective layer 350 on the fourth insulating interlayer 330.

In example embodiments, a plurality of third chip pads 342 may be spaced apart from each other in the second direction D2 on a portion of the fourth insulating interlayer 330 adjacent to the first edge E13 of the second substrate 310, and a plurality of fourth chip pads 346 may be spaced apart from each other in the first direction D1 on a portion of the fourth insulating interlayer 330 adjacent to the third edge E33 of the second substrate 310.

The second semiconductor chip 300 may be bonded with an upper surface of the first chip protective layer 250 included in the first semiconductor chip 200 by a second bonding layer 390 that is attached beneath the second surface 314 of the second substrate 310.

In example embodiments, the second semiconductor chip 300 may be stacked on the first semiconductor chip 200 to be offset with respect to the first semiconductor chip 300 in the first direction D1. The third chip pads 342 of the second semiconductor chip 300 may be aligned in the first direction D1 with the first chip pads 242, respectively, of the first semiconductor chip 200, and some of the fourth chip pads 346 of the second semiconductor chip 300 may overlap the second chip pads 246, respectively, of the second semiconductor chip 300 in the third direction D3. Thus, the second edge E22 of the first semiconductor chip 200 may be covered by the second semiconductor chip 300, in a plan view.

The third and fourth edges E33 and E43 of the second semiconductor chip 300 may be partially aligned with the third and fourth edges E32 and E42, respectively, of the first semiconductor chip 200 in the third direction D3.

A wire bonding process may be performed such that a first bonding wire 262 may contact the first substrate pad 122 of the package substrate structure 100 and the first chip pad 242 of the first semiconductor chip 200. Thus, the first substrate pad 122 and the first chip pad 242 may be electrically connected to each other.

Additionally, a third bonding wire 362 may contact the first chip pad 242 of the first semiconductor chip 200 and the third chip pad 342 of the second semiconductor chip 300, and thus the first chip pad 242 and the third chip pad 342 may be electrically connected to each other. Furthermore, a fourth bonding wire 366 may contact the third substrate pad 126 of the package substrate structure 100 and the fourth chip pad 346 of the second semiconductor chip 300, and thus the third substrate pad 126 and the fourth chip pad 346 may be electrically connected to each other.

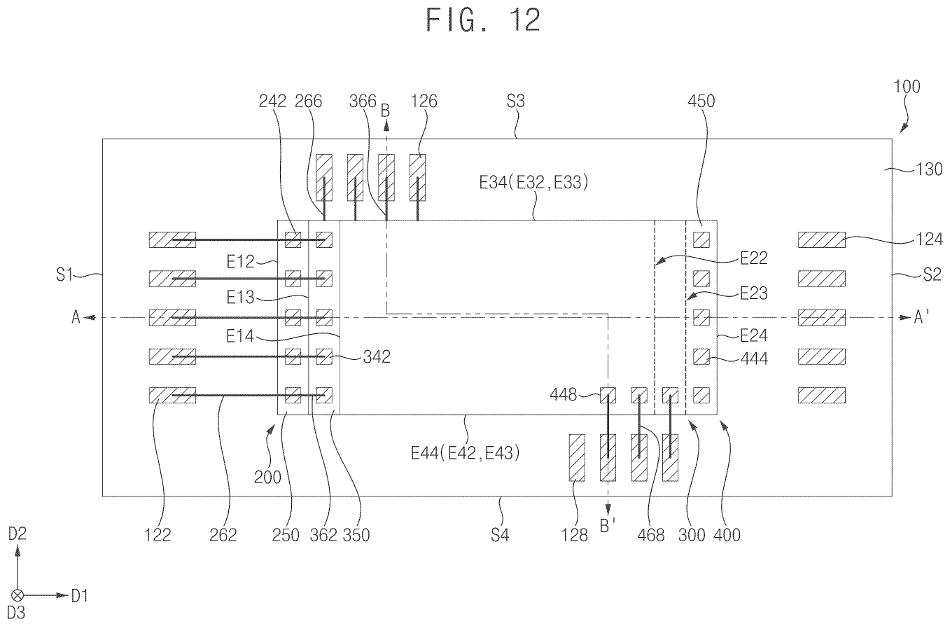

Referring to FIGS. 12 to 14, a third semiconductor chip 400 may be stacked on the second semiconductor chip 300.

The third semiconductor chip 400 may have a structure substantially the same as or similar to that of the first and second semiconductor chips 200 and 300. Thus, the third semiconductor chip 400 may include a third substrate 410 having first and second surfaces 412 and 414 opposite to each other in the third direction D3, and a fifth insulating interlayer and a sixth insulating interlayer 430 may be sequentially stacked on the first surface 412 of the third substrate 410.

The third substrate 410 may include first and second edges E14 and E24 opposite to each other in the first direction D1, and third and fourth edges E34 and E44 opposite to each other in the second direction D2. A circuit device including circuit patterns may be formed on the first surface 412 of the third substrate 410, which may be covered by the fifth insulating interlayer. The sixth insulating interlayer 430 may contain a wiring structure therein.

A third chip pad structure including fifth and sixth chip pads 444 and 448 may be formed on the sixth insulating interlayer 430, and may be electrically connected to the wiring structure in the sixth insulating interlayer 430. A sidewall of the third chip pad structure may be covered by a third chip protective layer 450 on the sixth insulating interlayer 430.

In example embodiments, a plurality of fifth chip pads 444 may be spaced apart from each other in the second direction D2 on a portion of the sixth insulating interlayer 430 adjacent to the second edge E24 of the third substrate 410, and a plurality of sixth chip pads 448 may be spaced apart from each other in the first direction D1 on a portion of the sixth insulating interlayer 430 adjacent to the fourth edge E44 of the third substrate 410.

The third semiconductor chip 400 may be bonded with an upper surface of the second chip protective layer 350 included in the second semiconductor chip 300 by a third bonding layer 490 that is attached beneath the second surface 414 of the third substrate 410. In example embodiments, the third semiconductor chip 400 may be stacked on the second semiconductor chip 300 to be offset with respect to the second semiconductor chip 300 in the first direction D1. The fifth and sixth chip pads 444 and 448 of the third semiconductor chip 400 may be disposed to be adjacent to the second and fourth substrate pads 124 and 128, respectively, of the package substrate structure 100.

The third and fourth edges E34 and E44 of the third semiconductor chip 400 may be partially aligned with the third and fourth edges E33 and E43, respectively, of the second semiconductor chip 300 in the third direction D3.

A wire bonding process may be performed such that a sixth bonding wire 468 may contact the fourth substrate pad 128 of the package substrate structure 100 and the sixth chip pad 448 of the third semiconductor chip 400. Thus, the fourth substrate pad 128 and the sixth chip pad 448 may be electrically connected to each other.

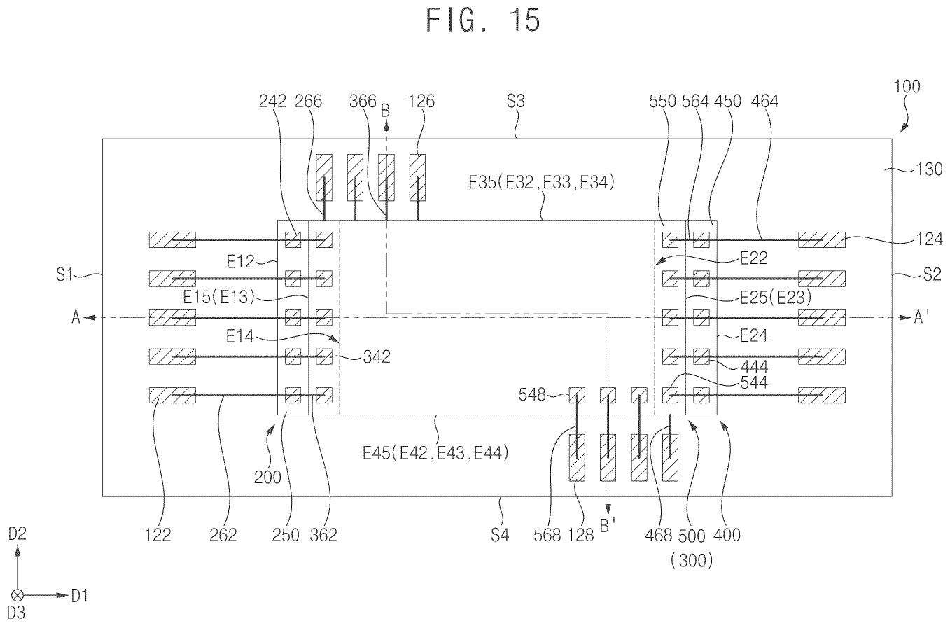

Referring to FIGS. 15 to 17, a fourth semiconductor chip 500 may be stacked on the third semiconductor chip 400.

In example embodiments, the fourth semiconductor chip 500 may have a structure substantially the same as or similar to that of the first to third semiconductor chips 200, 300 and 400. Thus, the fourth semiconductor chip 500 may include a fourth substrate 510 having first and second surfaces 512 and 514 opposite to each other in the third direction D3, and a seventh insulating interlayer and an eighth insulating interlayer 530 may be sequentially stacked on the first surface 512 of the fourth substrate 510.

The fourth substrate 510 may include first and second edges E15 and E25 opposite to each other in the first direction D1, and third and fourth edges E35 and E45 opposite to each other in the second direction D2. A circuit device including circuit patterns may be formed on the first surface 512 of the fourth substrate 510, which may be covered by the seventh insulating interlayer. The eighth insulating interlayer 530 may contain a wiring structure therein.

A fourth chip pad structure including seventh and eighth chip pads 544 and 548 may be formed on the eighth insulating interlayer 530, and may be electrically connected to the wiring structure in the eighth insulating interlayer 530. A sidewall of the fourth chip pad structure may be covered by a fourth chip protective layer 550 on the eighth insulating interlayer 530.

In example embodiments, a plurality of seventh chip pads 544 may be spaced apart from each other in the second direction D2 on a portion of the eighth insulating interlayer 530 adjacent to the second edge E25 of the fourth substrate 510, and a plurality of eighth chip pads 548 may be spaced apart from each other in the first direction D1 on a portion of the eighth insulating interlayer 530 adjacent to the fourth edge E45 of the fourth substrate 410.

The fourth semiconductor chip 500 may be bonded with an upper surface of the third chip protective layer 450 included in the third semiconductor chip 400 by the fourth bonding layer 590 that is attached beneath the second surface 514 of the fourth substrate 510. In example embodiments, the fourth semiconductor chip 500 may be stacked on the third semiconductor chip 400, and may be offset with respect to the third semiconductor chip 400 in the first direction D1. The seventh chip pads 544 of the fourth semiconductor chip 500 may be aligned in the first direction D1 with the fifth chip pads 444, respectively, of the third semiconductor chip 400, and some of the eighth chip pads 548 of the fourth semiconductor chip 500 may overlap the sixth chip pads 448, respectively, of the third semiconductor chip 400 in the third direction D3.

The third and fourth edges E35 and E45 of the fourth semiconductor chip 500 may be partially aligned with the third and fourth edges E34 and E44, respectively, of the third semiconductor chip 400 in the third direction D3.

A wire bonding process may be performed such that a fifth bonding wire 464 may contact the second substrate pad 124 of the package substrate structure 100 and the fifth chip pad 444 of the third semiconductor chip 400. Thus, the second substrate pad 124 and the fifth chip pad 444 may be electrically connected to each other. Additionally, a seventh bonding wire 564 may contact the seventh chip pad 544 of the fourth semiconductor chip 500 and the fifth chip pad 444 of the third semiconductor chip 400, and thus may electrically connect the seventh chip pad 544 and the fifth chip pad 444. Furthermore, an eighth bonding wire 568 may contact the fourth substrate pad 128 of the package substrate structure 100 and the eighth chip pad 548 of the fourth semiconductor chip 500, and thus may electrically connect the fourth substrate pad 128 and the eighth chip pad 548.

Referring to FIGS. 1 to 3 again, a molding member 600 may be formed on the package substrate structure 100 to cover the first to fourth semiconductor chips 200, 300, 400 and 500, the first to fourth bonding layers 290, 390, 490 and 590, and the first to eighth bonding wires 262, 266, 366, 464, 468, 564 and 568.

An external connection member 190 may be formed on the second surface 114 of the package substrate 110 to contact the fifth substrate pad 145 to complete the manufacturing the semiconductor package.

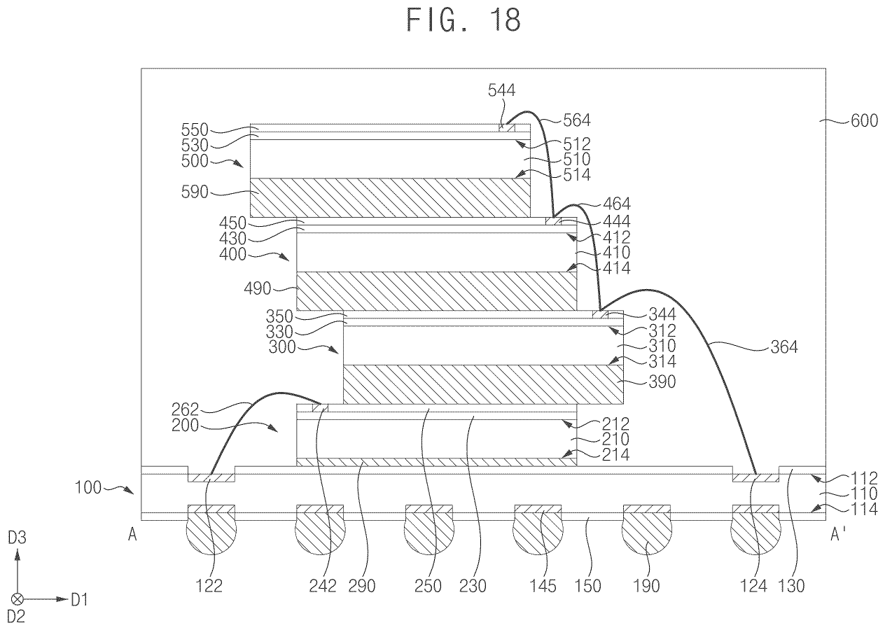

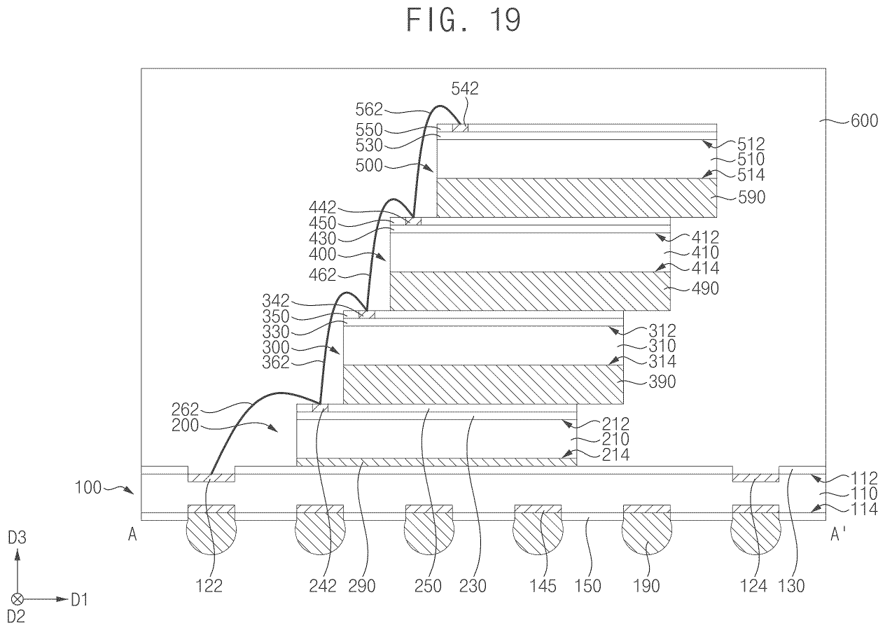

FIGS. 18 and 19 are cross-sectional views illustrating semiconductor packages in accordance with example embodiments, which may correspond to FIG. 2. These semiconductor packages may be substantially the same as or similar to that of FIGS. 1 to 3, except for the shape of the stack of the semiconductor chips, and thus repeated explanations are omitted herein.

Referring to FIG. 18, the third semiconductor chip 400 may be offset with respect to the second semiconductor chip 300 in a direction that is inverse to the direction in which the third semiconductor chip 400 is offset with respect to the second semiconductor chip 300 in the semiconductor package shown in FIGS. 1 to 3.

Thus, instead of the third chip pads 342 spaced apart from each other in the second direction D2 on a portion of the fourth insulating interlayer 330 adjacent to the first edge E13 of the second substrate 310, a plurality of ninth chip pads 344 may be spaced apart from each other in the second direction D2 on a portion of the fourth insulating interlayer 330 adjacent to the second edge E23 of the second substrate 310. A ninth bonding wire 364 may be formed between the second substrate pad 124 of the package substrate 110 and the ninth chip pad 344, and may electrically connect the second substrate pad 124 and the ninth chip pad 344.

The fifth bonding wire 464 may not be formed between the fifth chip pad 444 of the third semiconductor chip 400 and the second substrate pad 124 of the package substrate 110, but may be formed between the fifth chip pad 444 of the third semiconductor chip 400 and the ninth chip pad 344 of the second semiconductor chip 300.

Referring to FIG. 19, the first to fourth semiconductor chips 200, 300, 400 and 500 may be stacked in a cascade shape in the first direction D1.

Thus, instead of the fifth and seventh chip pads 444 and 544, tenth and eleventh chip pads 442 and 542 may be formed on the third and fourth semiconductor chips 400 and 500, respectively. A tenth bonding wire 462 may be formed between the third and tenth chip pads 342 and 442, and may electrically connect the third and tenth chip pads 342 and 442. An eleventh bonding wire 562 may be formed between the tenth and eleventh chip pads 442 and 542, and may electrically connect the tenth and eleventh chip pads 442 and 542.

That is, at least some of the semiconductor chips included in the semiconductor package in accordance with example embodiments may be stacked such that the side surfaces of the semiconductor chips that are adjacent to the signal pads may be arranged in a cascade shape. Bonding pads of the package substrate may not be connected to the signal pads, respectively, of the semiconductor chips by bonding wires, but may directly contact one of the signal pads, e.g., a lowermost one of the signal pads, and may be electrically connected to other ones of the signal pads by a chip-to-chip wire bonding method. Thus, the semiconductor package including the signal pads may have enhanced operation characteristics and a higher operation speed.

First ones of the chip pads adjacent to edges having a relatively large length in each semiconductor chip may serve as a signal pad, while second ones of the chip pads adjacent to edges having a relatively small length in each semiconductor chip may serve as a power pad or a ground pad, however, the inventive concepts may not be limited thereto, and the first ones of the chip pads may serve as the power pad or the ground pad and the second ones of the chip pads may serve as the signal pad.

Any semiconductor packages including signal pads in at least some of the semiconductor chips stacked in the vertical direction that are disposed in a cascade shape and are electrically connected to each other by a chip-to-chip wire bonding method, regardless of the shape of the stack of the semiconductor chips or the layouts of the signal pads, may be within the scope of the inventive concepts.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package comprising:
a package substrate having substrate pads;
semiconductor chips stacked in a vertical direction on the package substrate, the semiconductor chips including at least a first semiconductor chip and a second semiconductor chip;
a first bonding wire connecting a first chip pad of the first semiconductor chip with a corresponding one of a first set of the substrate pads;
a second bonding wire connecting another of the first set of substrate pads with a second chip pad of the second semiconductor chip;
a third bonding wire connecting a second substrate pad, among the substrate pads, and a third chip pad of the first semiconductor chip;
a fourth bonding wire contacting the third chip pad with a fourth chip pad of the second semiconductor chip; and
a molding member on the package substrate, the molding member covering the semiconductor chips and the first to fourth bonding wires.

2. The semiconductor package according to claim 1, wherein each of the semiconductor chips includes:
first and second edges, each of the first and second edges extending in a first direction to a first length, and the first and second edges being opposite to each other in a second direction crossing the first direction; and
third and fourth edges, each of the third and fourth edges extending in the second direction to a second length less than the first length, and the third and fourth edges being opposite to each other in the first direction, and
wherein the chip pads are adjacent to the first and third edges or are adjacent to the second and fourth edges, and are arranged in an “L” shape in a plan view.

3. The semiconductor package according to claim 2, wherein
the first chip pad is adjacent to one of the first edge or the second edge of the first semiconductor chip, and
the second chip pad is adjacent to one of the first edge or the second edge of the second semiconductor chip.

4. The semiconductor package according to claim 2, wherein
the third chip pad is adjacent to one of the third edge or the fourth edge of the first semiconductor chip, and
the fourth chip pad is adjacent to one of the third edge or the fourth edge of the second semiconductor chip.

5. The semiconductor package according to claim 2, wherein the first semiconductor chip further includes a plurality of first chip pads adjacent to one of the first edge or the second edge of the first semiconductor chip, the first chip pad being one of the plurality of first chip pads,
wherein the first semiconductor chip further includes a plurality of third chip pads adjacent to one of the third edge or the fourth edge of the first semiconductor chip, the third chip pad being one of the plurality of third chip pads, and
wherein a number of the plurality of third chip pads is greater than a number of the plurality of first chip pads.

6. The semiconductor package according to claim 2, wherein the second semiconductor chip is offset with respect to the first semiconductor chip in the first direction.

7. The semiconductor package according to claim 6, wherein the second semiconductor chip is offset with respect to the first semiconductor chip in the first direction by a distance within a range of 200 micrometers (um) to 300 um.

8. The semiconductor package according to claim 2, wherein the first and second edges of the second semiconductor chip partially overlap the first and second edges of the first semiconductor chip.

9. The semiconductor package according to claim 1, further comprising:
a fifth bonding wire connecting a corresponding one of a third set of the substrate pads with a fifth chip pad of a third semiconductor chip of the semiconductor chips stacked in the vertical direction;
a sixth bonding wire connecting another of the third set of substrate pads with a sixth chip pad of a fourth semiconductor chip of the semiconductor chips stacked in the vertical direction;
a seventh bonding wire connecting a fourth substrate pad, among the substrate pads, and with a seventh chip pad of the third semiconductor chip; and
an eighth bonding wire connecting the seventh chip pad with an eighth chip pad of the fourth semiconductor chip.

10. The semiconductor package according to claim 9, wherein each of the semiconductor chips includes:
first and second edges, each of the first and second edges extending in a first direction to a first length, and the first and second edges being opposite to each other in a second direction crossing the first direction; and
third and fourth edges, each of the third and fourth edges extending in the second direction to a second length less than the first length, and the third and fourth edges being opposite to each other in the first direction, and
wherein the chip pads are respectively adjacent to the first edge, the third edge, the second edge, and fourth edge such that the chip pads are arranged in an “L” shape in a plan view.

11. The semiconductor package according to claim 10, wherein
the fifth chip pad is adjacent to one of the first edge or the second edge of the third semiconductor chip, and
the sixth chip pad is adjacent to a corresponding one of the first edge or the second edge of the fourth semiconductor chip.

12. The semiconductor package according to claim 10, wherein
the seventh chip pad is adjacent to one of the third edge or the fourth edge of the third semiconductor chip, and
the eighth chip pad is adjacent to a corresponding one of the third edge or the fourth edge of the fourth semiconductor chip.

13. The semiconductor package according to claim 10, wherein the fourth semiconductor chip is offset with respect to the third semiconductor chip in the first direction.

14. The semiconductor package according to claim 10, wherein the first and second edges of the fourth semiconductor chip partially overlap the first and second edges of the third semiconductor chip.

15. The semiconductor package according to claim 1, wherein
each of the first and second chip pads is one of a power pad or a ground pad, and
each of the third and fourth chip pads is a signal pad.

16. A semiconductor package comprising:
a package substrate having substrate pads;
semiconductor chips stacked in a vertical direction on the package substrate, the semiconductor chips including at least a first semiconductor chip and a second semiconductor chip, and each of the semiconductor chips including
first and second edges, each of the first and second edges extending in a first direction to a first length, and the first and second edges being opposite to each other in a second direction crossing the first direction,
third and fourth edges, each of the third and fourth edges extending in the second direction to a second length less than the first length, and the third and fourth edges being opposite to each other in the first direction,
a first chip pad adjacent to at least one of the first edge or the second edge, and
a second chip pad adjacent to at least one of the third edge or the fourth edge;
a first bonding wire connecting the first chip pad of the first semiconductor chip with a corresponding one of a first set of the substrate pads;
a second bonding wire contacting another of the first set of substrate pads with the first chip pad of the second semiconductor chip;
a third bonding wire connecting a corresponding one of a second set of the substrate pads with the second chip pad of the first semiconductor chip;
a fourth bonding wire connecting the second chip pad of the first semiconductor chip with the second chip pad of the second semiconductor chip; and
a molding member on the package substrate, the molding member covering the semiconductor chips and the first to fourth bonding wires.

17. The semiconductor package according to claim 16, wherein the first and second chip pads are, respectively, at least adjacent to the first and third edges or adjacent to the second and fourth edges such that the first and second chip pads are arranged in an “L” shape in a plan view.

18. The semiconductor package according to claim 16, wherein the second semiconductor chip is offset with respect to the first semiconductor chip in the first direction.

19. A semiconductor package comprising:
a package substrate having substrate pads;
first, second, third and fourth semiconductor chips stacked in a vertical direction on the package substrate;
a first bonding wire connecting a first chip pad of the first semiconductor chip with a corresponding one of a first set of the substrate pads;
a second bonding wire connecting another of the first substrate pads with a second chip pad of the second semiconductor chip;
a third bonding wire connecting a third chip pad of the first semiconductor chip with a corresponding one of a second set of the substrate pads;
a fourth bonding wire connecting the third chip pad of the first semiconductor chip with a fourth chip pad of the second semiconductor chip;
a fifth bonding wire connecting a fifth chip pad of the third semiconductor chip with a corresponding one of a third set of the substrate pads;
a sixth bonding wire contacting another of the third substrate pads with a sixth chip pad of the fourth semiconductor chip;
a seventh bonding wire connecting a fourth substrate pad, among the substrate pads, with a seventh chip pad of the third semiconductor chip;
an eighth bonding wire connecting the seventh chip pad and an eighth chip pad of the fourth semiconductor chip; and
a molding member on the package substrate, the molding member covering the first to fourth semiconductor chips and the first to eighth bonding wires.

20. The semiconductor package according to claim 19, wherein each of the first to fourth semiconductor chips includes:
first and second edges, each of the first and second edges extending in a first direction to a first length, and the first and second edges being opposite to each other in a second direction crossing the first direction; and
third and fourth edges, each of the third and fourth edges extending in the second direction to a second length less than the first length, and the third and fourth edges being opposite to each other in the first direction,
wherein the chip pads are, respectively, adjacent to the first and third edges or the second and fourth edges such that the chip pads are arranged in an “L” shape in a plan view,
wherein the first chip pad is adjacent to at least one of the first edge or the second edge of the first semiconductor chip, and the second chip pad is adjacent to at least one of the first edge or the second edge of the second semiconductor chip, and
wherein the third chip pad is adjacent to at least one of the third edge or the fourth edge of the first semiconductor chip, and the fourth chip pad is adjacent to at least one of the third edge or the fourth edge of the second semiconductor chip.
